(19) United States
(12) Patent Application Publication
(10) Pub. No.: US 2012/0070948 A1
(43) Pub. Date: Mar. 22, 2012

(54) ADJUSTING METHOD OF CHANNEL STRESS

(75) Inventors: Tzyy-Ming CHENG, Hsinchu City (TW); Ching-Sen Lu, Tainan City (TW); Tsai-Fu Chen, Hsinchu City (TW); Wen-Han Hung, Kaohsiung City (TW); Ta-Kang Lo, Taoyuan County (TW); Chun-Yuan Wu, Yunlin County (TW); Shih-Fang Tzou, Hsinchu County (TW)

(73) Assignee: UNITED MICROELECTRONICS CORP., Hsinchu (TW)

(21) Appl. No.: 12/883,266

(22) Filed: Sep. 16, 2010

(51) Int. Cl. H01L 21/8238

(52) U.S. Cl. 438/199; 257/E21.632

(57) ABSTRACT

An adjusting method of channel stress includes the following steps. A substrate is provided. A metal-oxide-semiconductor field-effect transistor is formed on the substrate. The MOSFET includes a source/drain region, a channel, a gate, a gate dielectric layer and a spacer. A dielectric layer is formed on the substrate and covers the metal-oxide-semiconductor field-effect transistor. A flattening process is applied onto the dielectric layer. The remaining dielectric layer is removed to expose the source/drain region. A non-conformal high stress dielectric layer is formed on the substrate having the exposed source/drain region.

### BACKGROUND

1. Field of the Invention

The present invention relates to an adjusting method of channel stress, and particularly to an adjusting method of channel stress, which is applied to a fabrication of a metal-oxide-semiconductor field-effect transistor (MOSFET).

2. Description of the Related Art

In the technology for manufacturing an integrated circuit, a gate structure including an insulating layer with high dielectric constant (high-K) and a metal gate (hereafter called HK/MG for short) has been widely used. Such gate structure can reduce a current leakage, thereby improving the performance of the integrated circuit. Currently, the HK/MG can be selectively fabricated by two processes including a gate-first process and a gate-last process. In the gate-first process, the HK/MG is previously disposed before forming the gate structure. In the gate-last process, after a poly-silicon dummy gate is removed, the metal gate of the HK/MG is filled.

Referring to FIGS. 1(a)-1(b) illustrate a partial process flow of a conventional method for fabricating a MOSFET. In FIG. 1(a), at first, a source/drain region 101 and a channel 100 are defined in a substrate 10. A poly-silicon gate 11 coved by a hard mask 16 is formed on a gate dielectric layer 12 on the channel 100. If the gate-last process is applied, the poly-silicon gate 11 is a poly-silicon dummy gate surrounded by a spacer 13. The gate dielectric layer 12 can be a multiplayer structure as shown in FIG. 1(a), which includes a silicon oxide layer 120 and a high-K insulating layer 121. The spacer 13 also can be a multilayer structure shown in FIG. 1(a), which includes a first spacer 131 and a second spacer 132. Next, a contact etch stop layer (CESL) 14 is formed on the substrate 10 to cover the channel 100, the source/drain region 101, the poly-silicon gate 21, the gate dielectric layer 12 and the spacer 13. Next, an interlayer dielectric (ILD) layer 15 is formed on the contact etch stop layer 14. Referring to FIG. 1(b), for a flatness demand, a top cut chemical mechanical polishing process is performed to remove the partial structures on the substrate 10 to form a flat top surface. For example, as shown in FIG. 1(b), a part of the interlayer dielectric layer 15, a part of the contact etch stop layer 14 and the hard mask 16 are removed, thereby forming a structure so as to perform the subsequent steps, for example, removing the poly-silicon dummy gate and filling the metal gate substituting.

Because the length of the gate can not be limitlessly reduced any more and new materials have not been proved to be used in the MOSFET, adjusting mobility has been an important role to improve the performance of the integrated circuit. The lattice strain of the channel 100 is widely applied to increase mobility during fabricating the MOSFET. For example, the hole mobility of the silicon with the lattice strain can be 4 times as many as the hole mobility of the silicon without the lattice strain, and the electron mobility with the lattice strain can be 1.8 times as many as the electron mobility of the silicon without the lattice strain.

Therefore, a tensile stress can be applied to an N-channel of an N-channel MOSFET by changing the structure of the transistor, or a compression stress can be applied to a P-channel of a P-channel MOSFET by changing the structure of the transistor. The channel is stretched, which can improve the electron mobility, and the channel is compressed, which can improve the hole mobility. Generally, a silicon nitride (SiN) film is formed after the components of the MOSFET are finished. The silicon nitride film has a characteristic of high stress that is used for controlling the stress in the channel. According to various depositing conditions, the silicon nitride film can provide a tensile stress so as to increase the electron mobility of the N-channel. Also, the silicon nitride can provide a compression stress so as to increase the electron mobility of the P-channel. Additionally, the carrier (electron/hole) mobility can also be improved by controlling the silicon nitride film to have various thicknesses.

Thus, the contact etch stop layer 14 has another important function of generating the stress applied to the channel 100 to increase the carrier mobility except the inherent function of stopping etching during an etching process for forming a contact hole. In general, the contact etch stop layer 14 comprised of a material of silicon nitride is formed right on the MOSFET. The contact etch stop layer 14 can adjust the lattice strain of the channel of the MOSFET through the tensile stress or the compression stress of the contact etch stop layer 14, thereby increasing the carrier mobility.

However, when the contact etch stop layer 14 is damaged by the above-mentioned top cut chemical mechanical polishing process, the stress applied to the channel will change tremendously, thereby having a bad effect on the carrier mobility.

Therefore, what is needed is an adjusting method of channel stress to overcome the above disadvantages.

### BRIEF SUMMARY

The present invention provides an adjusting method of channel stress. The method includes the following steps. A substrate is provided. A MOSFET is formed on the substrate. The MOSEFT includes a source/drain region, a channel, a gate, a gate dielectric layer and a spacer. A dielectric layer is formed on the substrate and covers the MOSFET. A flattening process is applied onto the dielectric layer. The remaining dielectric layer is removed to expose the source/drain region. A non-conformal high stress dielectric layer is formed on the substrate having the exposed source/drain region.

The present invention also provides an adjusting method of channel stress. The method includes the following steps. A substrate is provided. A MOSEFT is formed on the substrate. The MOSEFT includes a source/drain region, a channel, a dummy gate, a gate dielectric layer and a spacer. A dielectric layer is formed on the substrate and covers the MOSEFT. A flattening process is applied onto the dielectric layer so as to expose the dummy gate of the MOSFET. The dummy gate is removed and a metal gate is filled to substitute for the dummy gate. The remaining dielectric layer is removed to expose the source/drain region. A non-conformal high stress dielectric layer is formed on the substrate having the exposed source/drain region to cover the MOSFET.

In one embodiment of the present invention, the substrate is a silicon substrate. The gate and the dummy gate is a poly-silicon gate respectively. The gate dielectric layer includes a silicon oxide layer and a high-K insulating layer. The spacer includes a first spacer and a second spacer.

In one embodiment of the present invention, the dielectric layer includes a contact etch stop layer and an interlayer dielectric layer. A method of forming the dielectric layer includes the steps of forming the contact etch stop layer on the substrate to cover the MOSFET, and forming the interlayer dielectric layer on the contact etch stop layer.

In one embodiment of the present invention, the contact etch stop layer is a stress film of stress memorization technique (SMT). The flattening process is a chemical mechanical polishing process.

In one embodiment of the present invention, the non-conformal high stress dielectric layer can be either a non-conformal high tensile stress dielectric layer or a non-conformal high compression stress dielectric layer. The non-conformal high tensile stress dielectric layer is configured for being formed on the source/drain region of an N-channel MOSFET, and the non-conformal high compression stress dielectric layer is configured for being formed on the source/drain region of a P-channel MOSFET.

In one embodiment of the present invention, the source/drain region includes a recess. The non-conformal high stress dielectric layer is filled in the recess. A material of the interlayer dielectric layer includes either silicon oxide or polymer.

In the method of the present invention, after the remaining dielectric layer is removed, a non-conformal high stress dielectric layer is formed so as to provide a tensile stress or a compression stress for the channel of the MOSFET, thereby improving the carrier mobility.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

These and other features and advantages of the various embodiments disclosed herein will be better understood with respect to the following description and drawings, in which like numbers refer to like parts throughout, and in which:

FIGS. 1(a)-1(b) illustrate a partial process flow of a conventional method for fabricating a MOSFET.

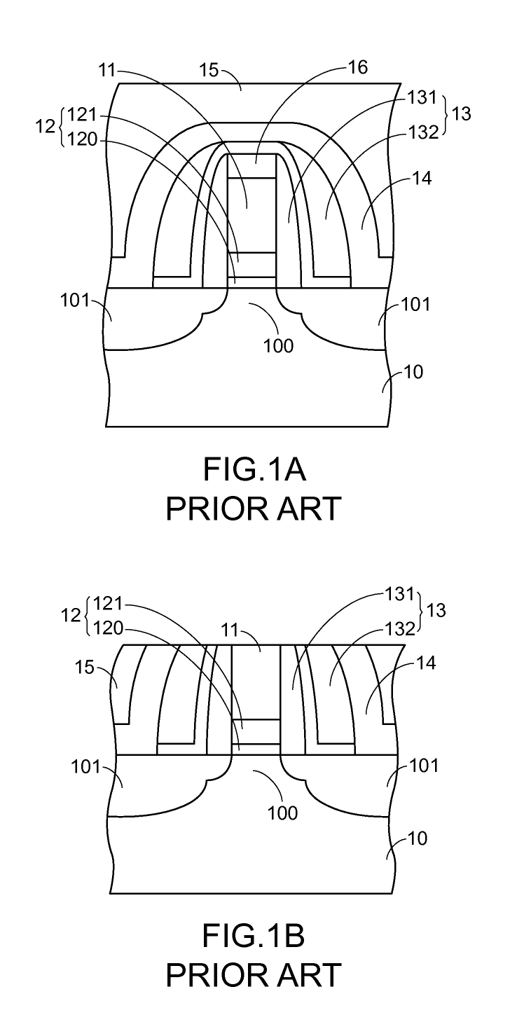

FIGS. 2(a)-2(e) illustrate a partial process flow of a method for fabricating a MOSFET in accordance with first embodiment of the present invention.

FIG. 3 illustrates a schematic view of a MOSFET in accordance with first embodiment of the present invention.

FIGS. 4(a)-2(d) illustrate a partial process flow of a method for fabricating a MOSFET in accordance with second embodiment of the present invention.

FIG. 5 illustrates a schematic view of a MOSFET in accordance with first embodiment of the present invention.

### DETAILED DESCRIPTION

It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings.

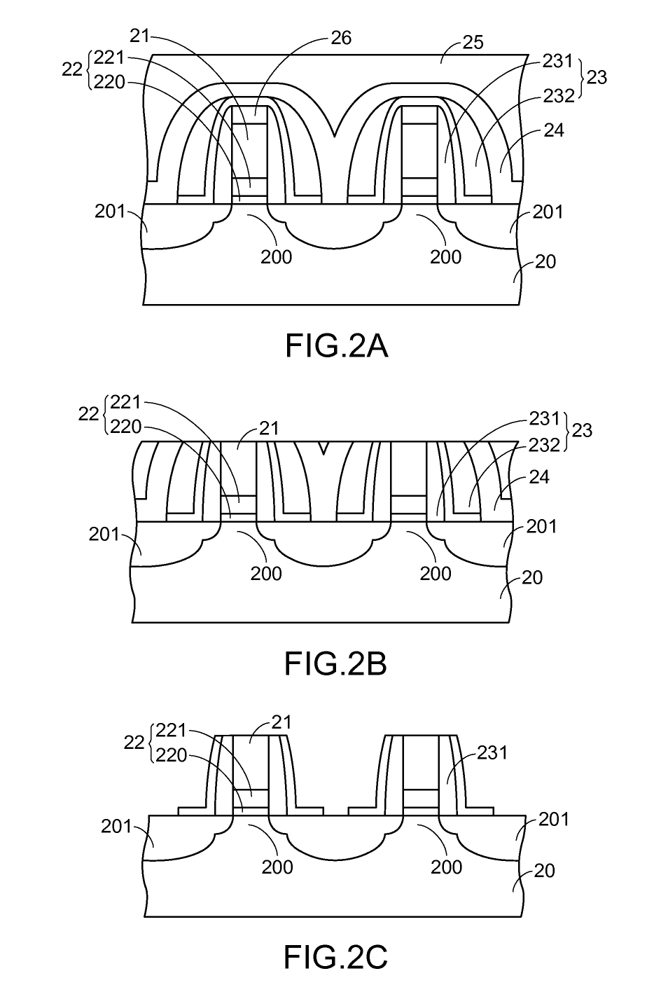

FIGS. 2(a)-2(e) illustrate a partial process flow of a method for fabricating a MOSFET in accordance with first embodiment of the present invention. Referring to FIG. 2(a), a source/drain region 201 and a channel 200 are defined in a substrate 20. A gate 21 coved by a hard mask 26 is formed on a gate dielectric layer 22 on the channel 200. The gate 21 can be made of a silicon-containing material, for example, doped silicon, undoped silicon, poly-silicon, or amorphous silicon. If the gate-last process is applied, the gate 21 is a poly-silicon dummy gate and a barrier layer (not shown) is disposed between the gate dielectric layer 22 and the gate 21. A material of the barrier layer can be, for example, titanium nitride or tantalum nitride. The gate 21 is surrounded by a spacer 23. If the gate-first process is applied, a work function metal layer (not shown) is disposed between the gate 21 and the gate dielectric layer 22. The gate dielectric layer 22 can be a multiplayer structure as shown in FIG. 2(a), which includes a silicon oxide layer 220 and a high-K insulating layer 221. The spacer 23 also can be a multilayer structure shown in FIG. 2(a), which includes a first spacer 231 and a second spacer 232. The first spacer 231 can be either a composite layer structure including a silicon oxide layer and a silicon nitride layer, or a pure silicon oxide layer. The second spacer 232 can be either a composite layer structure including a silicon oxide layer and a silicon nitride layer, or a composite layer structure including a silicon nitride layer, a silicon oxide layer and a silicon nitride layer. Next, a contact etch stop layer (CESL) 24 is formed on the substrate 20 to cover the channel 200, the source/drain region 201, the gate 21, the gate dielectric layer 22 and the spacer 23. Next, an interlayer dielectric (ILD) layer 25 is formed on the contact etch stop layer 24.

Similarly, referring to FIG. 2(b), a flattening process, such as a top cut chemical mechanical polishing process is applied onto the interlayer dielectric layer 25 to remove the partial structures on the substrate 20 to form a flat top surface. For example, as shown in FIG. 2(b), a part of the interlayer dielectric layer 25, a part of the contact etch stop layer 24, the hardmask 26, and so on, are removed. As a result, a portion of the MOSFET including the gate 21 and the spacer 23, is exposed from the flattened interlayer dielectric layer 25 and the flattened contact etch stop layer 24. It is noted that, in the flattening process, a top portion of the spacer 23 can also be removed.

Because the contact etch stop layer 24 is damaged in the step of the top cut chemical mechanical polishing process, the contact etch stop layer 24 has lost the function of generating the stress applied to the channel 200. Furthermore, the contact etch stop layer 24 is far away from the channel 200. In order to ensure provide a stress for the channel 200 directly, in the present invention, the remaining interlayer dielectric layer 25 and the remaining contact etch stop layer 24 are entirely removed by a dry etching method or a wetting etching method. Thus, the source/drain region 201 is exposed. Preferably, in order to increase the effect of applying the stress, the second spacer 232 can also be partially or entirely removed by a dry etching method or a wetting etching method, as shown in FIG. 2(c).

Next, a new dielectric layer, for example, a non-conformal high stress dielectric layer 27 is formed on the substrate 20 having the exposed source/drain region 201 to cover the MOSFET, as shown in FIG. 2(d). If an N-channel MOSFET is formed, the non-conformal high stress dielectric layer 27 is a non-conformal high tensile stress dielectric layer. If a P-channel MOSFET is formed, the non-conformal high stress dielectric layer 27 is a non-conformal high compression stress dielectric layer. A material of the non-conformal high stress dielectric layer 27 can be either silicon nitride or spin-on glass (SOG) of silicon oxide.

Next, another chemical mechanical polishing process is applied onto the non-conformal high stress dielectric layer 27, as shown in FIG. 2(e). The subsequent steps, for example, removing the poly-silicon gate 21, are similar to the conventional steps and are not described here.

In addition, the contact etch stop layer 24 can be a stress film of stress memorization technique (SMT). In detail, the exposed source/drain region 201 is non-crystallized so that the poly-silicon source/drain region 201 is transformed into the amorphous silicon source/drain region 201. Then, the contact etch stop layer 24 acts as the stress film is formed to cover the amorphous silicon source/drain region 201. Subsequently, an annealing thermal treatment is performed so that the source/drain region 201 can memorize the stress effect of the contact etch stop layer 24. Thereafter, the interlayer dielectric layer 25 is formed on the contact etch stop layer 24. Afterwards, the above mentioned flattening process is performed and the non-conformal high stress dielectric layer 27 is formed on the flattened substrate 20.

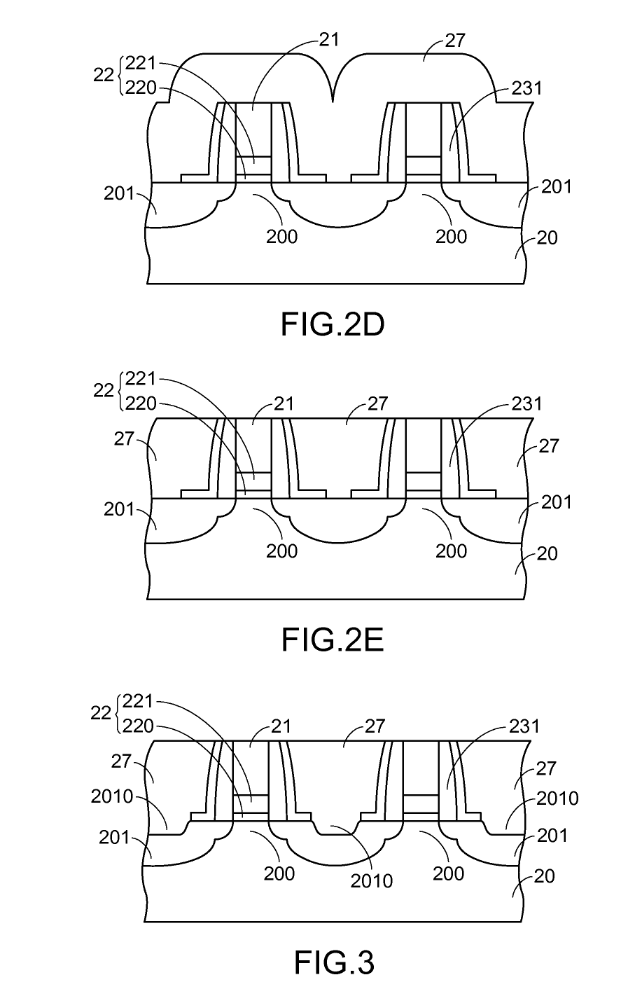

Additionally, in the present embodiment, the source/drain region 201 can includes a recess 2010 as shown in FIG. 3. A method for forming the recess 2010 including the steps of forming a preformed recess (not shown) in the substrate 20, forming an epitaxial layer including silicon and other materials. A top surface of the epitaxial layer is lower than the surface of the substrate, thereby forming the recess 2010. The non-conformal high stress dielectric layer 27 is filled into the recess 2010 so that the non-conformal high stress dielectric layer 27 can provide better stress effect for the channel 200. The non-conformal high stress dielectric layer 27 can extends into the substrate 20 to apply the stress to the channel 200, thereby achieving better effect of the lattice strain of the channel 200.

A material of the interlayer dielectric layer 25 can includes silicon oxide. Also, the material of the interlayer dielectric layer 25 can be other suitable materials, for example, polymer. It is considered whether the material of the interlayer dielectric layer 25 is suitable for the top cut chemical mechanical polishing process and whether the material of the interlayer dielectric layer 25 causes the environmental pollution in the top cut chemical mechanical polishing process.

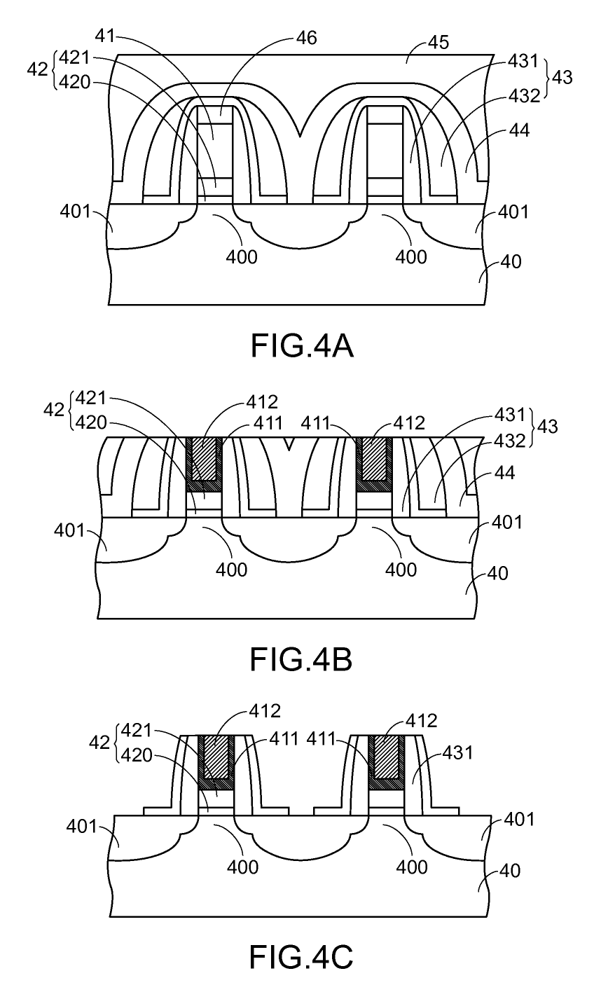

FIGS. 4(a)-4(d) illustrate a partial process flow of a method for fabricating a MOSFET in accordance with second embodiment of the present invention. Referring to FIG. 4(a), a source/drain region 401 and a channel 400 are defined in a substrate 40. A dummy gate, for example, a poly-silicon dummy gate 41 coved by a hard mask 46 is formed on a gate dielectric layer 42 on the channel 400. The dummy gate can be made of other silicon-containing material, for example, doped silicon, undoped silicon, or amorphous silicon. The poly-silicon dummy gate 41 is surrounded by a spacer 43. The gate dielectric layer 42 can be a multiplayer structure as shown in FIG. 4(a), which includes a silicon oxide layer 420 and a high-K insulating layer 421. A barrier layer (not shown) can be selectively formed between the poly-silicon dummy gate 41 and the gate dielectric layer 42. The barrier layer usually includes metal element and is configured for avoiding mis-match between the poly-silicon dummy gate 41 and the high-K insulating layer 421 and serving as an etch stop layer in the subsequent step of removing the poly-silicon dummy gate 41. A material of the barrier layer can be, for example, titanium nitride or tantalum nitride. The spacer 43 also can be a multilayer structure shown in FIG. 4(a), which includes a first spacer 431 and a second spacer 432. Next, a contact etch stop layer 44 is formed on the substrate 40 to cover the channel 400, the source/drain region 401, the poly-silicon dummy gate 41, the gate dielectric layer 42 and the spacer 43. Next, an interlayer dielectric layer 45 is formed on the contact etch stop layer 44.

Similarly, referring to FIG. 4(b), a flattening process, such as a top cut chemical mechanical polishing process is applied onto the onto the interlayer dielectric layer 45 to remove the partial structures on the substrate 40 to form a flat top surface. For example, as shown in FIG. 4(b), a part of the interlayer dielectric layer 45, a part of the contact etch stop layer 44, the hard mask 46, and so on, are removed. As a result, a portion of the MOSFET including the poly-silicon dummy gate 41 and the spacer 43 is exposed from the flattened dielectric layer 45 and the flattened contact etch stop layer 44. It is noted that, in the flattening process, a top portion of the spacer 43 can also be removed. Next, the poly-silicon dummy gate 41 on the barrier layer is removed and a work function metal layer 411 and a low resistance metal structure 412 are filled to substitute for the poly-silicon dummy gate 41.

The remaining interlayer dielectric layer 45 and the damaged remaining contact etch stop layer 44 are entirely removed by a dry etching method or a wetting etching method. Thus, the source/drain region 401 is exposed. Preferably, in order to increase the effect of applying the stress, the second spacer 432 can also be partially or entirely removed by a dry etching method or a wetting etching method, as shown in FIG. 4(c).

Next, a new dielectric layer, for example, a non-conformal high stress dielectric layer 47 is formed on the substrate 40 having the exposed source/drain region 401 to cover the MOSFET, as shown in FIG. 4(d). If an N-channel MOSFET is formed, the non-conformal high stress dielectric layer 47 is a non-conformal high tensile stress dielectric layer. If a P-channel MOSFET is formed, the non-conformal high stress dielectric layer 47 is a non-conformal high compression stress dielectric layer. Because the metal gate structure has replaced the poly-silicon dummy gate 41 in the present embodiment, the non-conformal high stress dielectric layer 47 will not be subjected to the top cut chemical mechanical polishing process to expose the gate. Thus, the non-conformal high stress dielectric layer 47 will not be damaged.

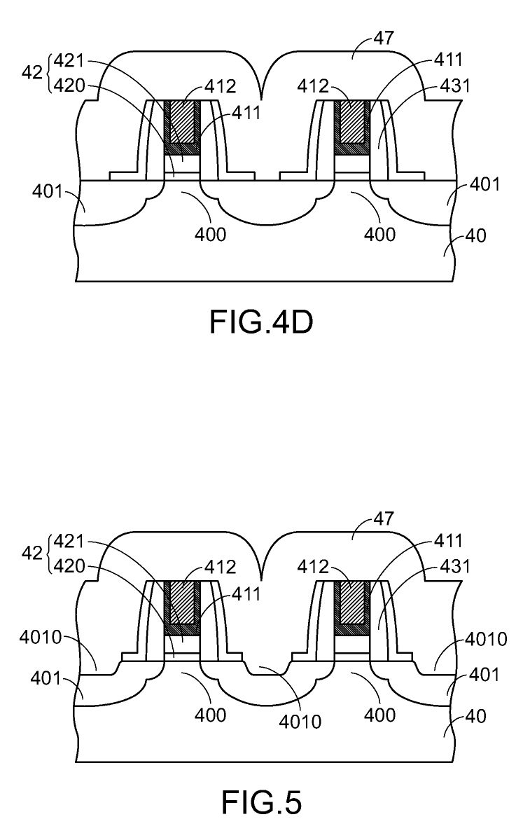

The contact etch stop layer 44 can also be a stress film of stress memorization technique. The source/drain region 401 can also includes a recess 4010 as shown in FIG. 5. The non-conformal high stress dielectric layer 47 is filled into the recess 4010 so that the non-conformal high stress dielectric layer 47 can provide better stress effect for the channel 400. A material of the interlayer dielectric layer 45 can includes silicon oxide. Also, the material of the interlayer dielectric layer 45 can be other suitable materials, for example, polymer. It is considered whether the material of the interlayer dielectric layer 45 is suitable for the top cut chemical mechanical polishing process and whether the material of the interlayer dielectric layer 45 causes the environmental pollution in the top cut chemical mechanical polishing process.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

1. An adjusting method of channel stress, comprising:
providing a substrate;
forming a metal-oxide-semiconductor field-effect transistor on the substrate, the metal-oxide-semiconductor field-effect transistor comprising a source/drain region, a channel, a gate, a gate dielectric layer and a spacer;
forming a dielectric layer on the substrate and covering the metal-oxide-semiconductor field-effect transistor;
applying a first flattening process onto the dielectric layer;
removing the remaining dielectric layer to expose the source/drain region;
forming a non-conformal high stress dielectric layer on the substrate having the exposed source/drain region, the non-conformal high stress dielectric layer being made of a single material; and
applying a second flattening process onto the non-conformal high stress dielectric layer directly.

2. The adjusting method of channel stress as claimed in claim 1, wherein the substrate is a silicon substrate, and the gate is a silicon-containing gate.

3. The adjusting method of channel stress as claimed in claim 1, wherein the gate dielectric layer comprises a silicon oxide layer and a high-K insulating layer.

4. The adjusting method of channel stress as claimed in claim 1, wherein the spacer at least comprises a first spacer and a second spacer.

5. The adjusting method of channel stress as claimed in claim 1, wherein the dielectric layer comprises a contact etch stop layer and an interlayer dielectric layer, and forming the dielectric layer comprises the steps of:
forming the contact etch stop layer on the substrate to cover the metal-oxide-semiconductor field-effect transistor; and
forming the interlayer dielectric layer on the contact etch stop layer.

6. The adjusting method of channel stress as claimed in claim 5, wherein the contact etch stop layer is a stress film of stress memorization technique.

7. The adjusting method of channel stress as claimed in claim 1, wherein the first flattening process and the second flattening process both are a chemical mechanical polishing process, and the first flattening process and the second flattening process both are configured for exposing the gate of the metal-oxide-semiconductor field-effect transistor.

8. The adjusting method of channel stress as claimed in claim 1, wherein the non-conformal high stress dielectric layer comprises either a non-conformal high tensile stress dielectric layer or a non-conformal high compression stress dielectric layer, the non-conformal high tensile stress dielectric layer is configured for being formed on the source/drain region of an N-channel metal-oxide-semiconductor field-effect transistor, and the non-conformal high compression stress dielectric layer is configured for being formed on the source/drain region of a P-channel metal-oxide-semiconductor field-effect transistor.

9. The adjusting method of channel stress as claimed in claim 1, wherein the source/drain region comprises a recess, and the non-conformal high stress dielectric layer is filled in the recess.

10. The adjusting method of channel stress as claimed in claim 5, wherein a material of the interlayer dielectric layer comprises either silicon oxide or polymer.

11. An adjusting method of channel stress, comprising:
providing a substrate;
forming a metal-oxide-semiconductor field-effect transistor on the substrate, the metal-oxide-semiconductor field-effect transistor comprising a source/drain region, a channel, a dummy gate, a gate dielectric layer and a spacer;
forming a dielectric layer on the substrate and covering the metal-oxide-semiconductor field-effect transistor;
applying a flattening process onto the dielectric layer to expose the dummy gate of the metal-oxide-semiconductor field-effect transistor;
removing the dummy gate;
filling a metal to substitute for the dummy gate;
removing the remaining dielectric layer to expose the source/drain region; and
forming a non-conformal high stress dielectric layer on the substrate having the exposed source/drain region to cover the metal-oxide-semiconductor field-effect transistor, the non-conformal high stress dielectric layer being made of a single material.

12. The adjusting method of channel stress as claimed in claim 11, wherein the substrate is a silicon substrate, and the dummy gate is a silicon-containing gate.

13. The adjusting method of channel stress as claimed in claim 11, wherein the gate dielectric layer comprises a silicon oxide layer and a high-K insulating layer.

14. The adjusting method of channel stress as claimed in claim 11, wherein the spacer at least comprises a first spacer and a second spacer.

15. The adjusting method of channel stress as claimed in claim 11, wherein the dielectric layer comprises a contact etch stop layer and an interlayer dielectric layer, and forming the dielectric layer comprises the steps of:
forming the contact etch stop layer on the substrate to cover the metal-oxide-semiconductor field-effect transistor; and
forming the interlayer dielectric layer on the contact etch stop layer.

16. The adjusting method of channel stress as claimed in claim 15, wherein the contact etch stop layer is a stress film of stress memorization technique.

17. The adjusting method of channel stress as claimed in claim 11, wherein the flattening process is a chemical mechanical polishing process.

18. The adjusting method of channel stress as claimed in claim 11, wherein the non-conformal high stress dielectric layer comprises either a non-conformal high tensile stress dielectric layer or a non-conformal high compression stress dielectric layer, the non-conformal high tensile stress dielectric layer is configured for being formed on the source/drain region of an N-channel metal-oxide-semiconductor field-effect transistor, and the non-conformal high compression stress dielectric layer is configured for being formed on the source/drain region of a P-channel metal-oxide-semiconductor field-effect transistor.

19. The adjusting method of channel stress as claimed in claim 11, wherein the source/drain region comprises a recess, and the non-conformal high stress dielectric layer is filled in the recess.

20. The adjusting method of channel stress as claimed in claim 15, wherein a material of the interlayer dielectric layer comprises either silicon oxide or polymer.

21. The adjusting method of channel stress as claimed in claim 1, before forming the non-conformal high stress dielectric layer, the spacer is either partially or entirely removed.

22. The adjusting method of channel stress as claimed in claim 11, before forming the non-conformal high stress dielectric layer, the spacer is either partially or entirely removed.
